(19) United States
(12) Patent Application Publication
(10) Pub. No.: US 2016/0099279 A1
(43) Pub. Date: Apr. 7, 2016

(54) IMAGE SENSOR WITH DEEP WELL STRUCTURE AND FABRICATION METHOD THEREOF

(71) Applicant: Powerchip Technology Corporation, Hsinchu (TW)

(72) Inventors: Chih-Ping Chung, Hsinchu City (TW); Chih-Hao Peng, Taoyuan County (TW); Ming-Yu Ho, Taichung City (TW); Saysamone Pittikoun, Hsinchu County (TW)

(21) Appl. No.: 14/549,506

(22) Filed: Nov. 20, 2014

(30) Foreign Application Priority Data
Oct. 3, 2014 (TW) 103134641

(51) Int. Cl. H01L 27/146

(52) U.S. Cl. CPC H01L 27/14645; H01L 27/14621; H01L 27/14627; H01L 27/1463; H01L 27/1461; H01L 27/14685; H01L 27/14683

(57) ABSTRACT

An image sensor device includes a substrate having a first conductivity type. A plurality of photo-sensing regions including a first, a second, and a third photo-sensing regions corresponding to the R, G, B pixels are provided on the substrate. An insulation structure is disposed on the substrate to separate the photo-sensing regions from one another. A photodiode structure is formed within each photo-sensing region. A deep well structure having a second conductivity type. The deep well structure only overlaps with the second and third photo-sensing regions. The deep well structure does not overlap with the first photo-sensing region.

### CROSS REFERENCE TO RELATED APPLICATION

This application claims the benefit of Taiwan patent application No. 103134641, filed on Oct. 3, 2014, the disclosure of which is incorporated herein in its entirety by reference.

### BACKGROUND OF THE INVENTION

1. Field of the Invention

The present invention relates to an image sensor device and, more particularly, to a CMOS image sensor having a deep well structure, which is capable of reducing the pixel cross talk, and improving the quantum efficiency.

2. Description of the Prior Art

CMOS active pixel sensors are known in the art. The active pixel sensor refers to an electronic image sensor with active elements such as transistors, associated with each pixel. As it is compatible with the CMOS process, an advantage is the ability to integrate signal processing and sensor circuitry within the same integrated circuit.

Above CMOS active pixel sensor is typically composed of four transistors and a “pinned” photodiode. The pinned photodiode can improve dark current and image lag, and has good color response to blue light. The surface potential of the diode is “pinned” through the P+ region in P well or the P substrate (ground) to reduce the dark current.

However, the above CMOS active pixel sensor encounters decreased sensitivity and cross talk in the infrared wavelength range (wavelengths of from about 700 nm to about 1 mm). This is because the absorption depth in this wavelength range is greater than the pixel depth. Crosstalk is increased because the light projected to the image sensor travels deep into the silicon surface of the image sensor and generates electron-hole pairs in silicon substrate, which is beyond the collecting range of pixels. Therefore, the photo-generated carriers diffuse freely in all directions. The sensitivity of above-described CMOS image sensor in the far-red to infrared wavelength range is reduced because many carriers generated deep within the substrate recombine.

From this, the need remains in the art for an improved image sensor and its manufacturing method capable of reducing crosstalk between the pixels, and can improve the quantum efficiency.

### SUMMARY OF THE INVENTION

According to one aspect of the invention, an image sensor device includes a semiconductor substrate having a first conductivity type. A plurality of photo-sensing regions including a first, a second and a third photo-sensing regions corresponding to the R, G, B pixels are provided on the semiconductor substrate. An insulation structure is disposed on the semiconductor substrate to separate the photo-sensing regions from one another. A light-sensing structure is formed within each photo-sensing region. A deep well structure having a second conductivity type. The deep well structure only overlaps with the second and third photo-sensing regions. The deep well structure does not overlap with the first photo-sensing region.

According to one embodiment of the invention, the first conductivity type is P type and the second conductivity type is N type.

According to one embodiment of the invention, the semiconductor substrate comprises an epitaxial layer. According to one embodiment of the invention, the epitaxial layer is a P− epitaxial silicon layer grown on a P+ silicon substrate.

According to one embodiment of the invention, the light-sensing structure comprises a diode structure that is composed of a lightly doped well and a heavily doped surface layer. According to one embodiment of the invention, the lightly doped well has the second conductivity type and the heavily doped surface layer has the first conductivity type.

According to one embodiment of the invention, the image sensor device further comprises a dielectric layer on the surface of the semiconductor substrate. According to one embodiment of the invention, the image sensor device further comprises a color filter film and a micro-lens layer disposed on the dielectric layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic, cross-sectional diagram showing a structure of an image sensor device according to one embodiment of the invention.

FIG. 2 shows an exemplary R/G/B pixels array corresponding to the photo-sensing regions of the image sensor device according to the embodiment of the invention.

FIG. 3 to FIG. 6 are schematic diagrams showing a method for fabricating an image sensor device according to another embodiment of the invention.

### DETAILED DESCRIPTION

In the following detailed description of the invention, reference is made to the accompanying drawings which form a part hereof, and in which is shown, by way of illustration, specific embodiments in which the invention may be practiced. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined by the appended claims.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terms wafer and substrate used herein include any structure having an exposed surface onto which a layer is deposited according to the present invention, for example, to form the integrated circuit (IC) structure. The term substrate is understood to include semiconductor wafers. The term substrate is also used to refer to semiconductor structures during processing, and may include other layers that have been fabricated thereupon. Both wafer and substrate include doped and undoped semiconductors, epitaxial semiconductor layers supported by a base semiconductor or insulator, as well as other semiconductor structures well known to one skilled in the art.

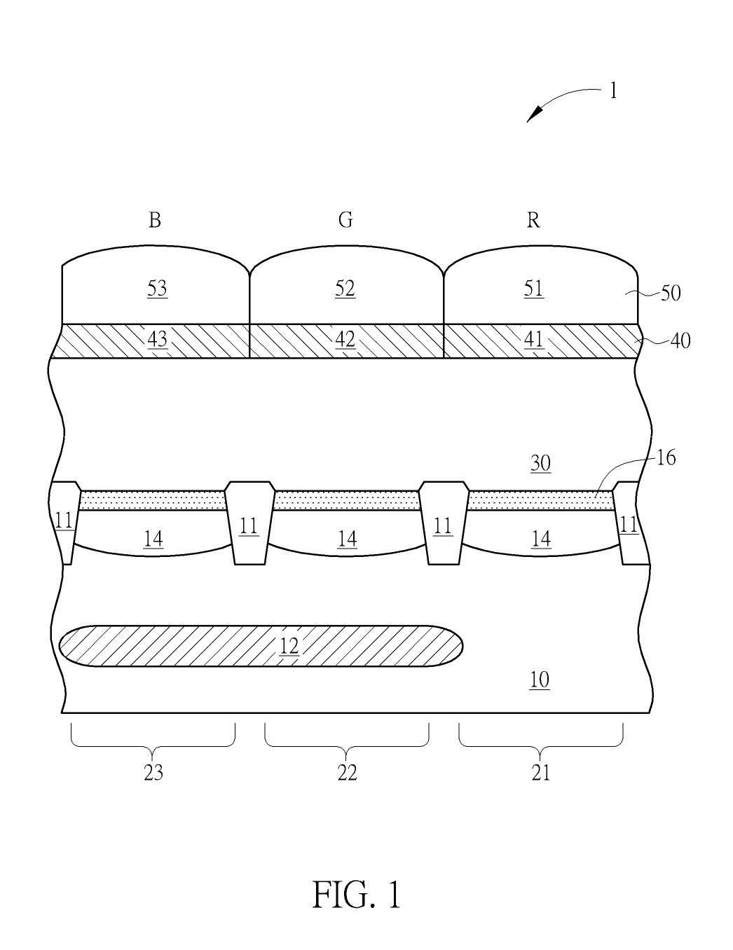

Please refer to FIG. 1. FIG. 1 is a schematic, cross-sectional diagram showing a structure of an image sensor device according to one embodiment of the invention. As shown in FIG. 1, the image sensor device 1 may be a CMOS image sensor device. The image sensor device 1 comprises a substrate 10, for example, a semiconductor substrate, having a first conductivity type such as P type. According to the embodiment, the substrate 10 may comprise an epitaxial layer (not shown), for example, a P− epitaxial silicon layer grown on a P+ silicon substrate, but not limited thereto.

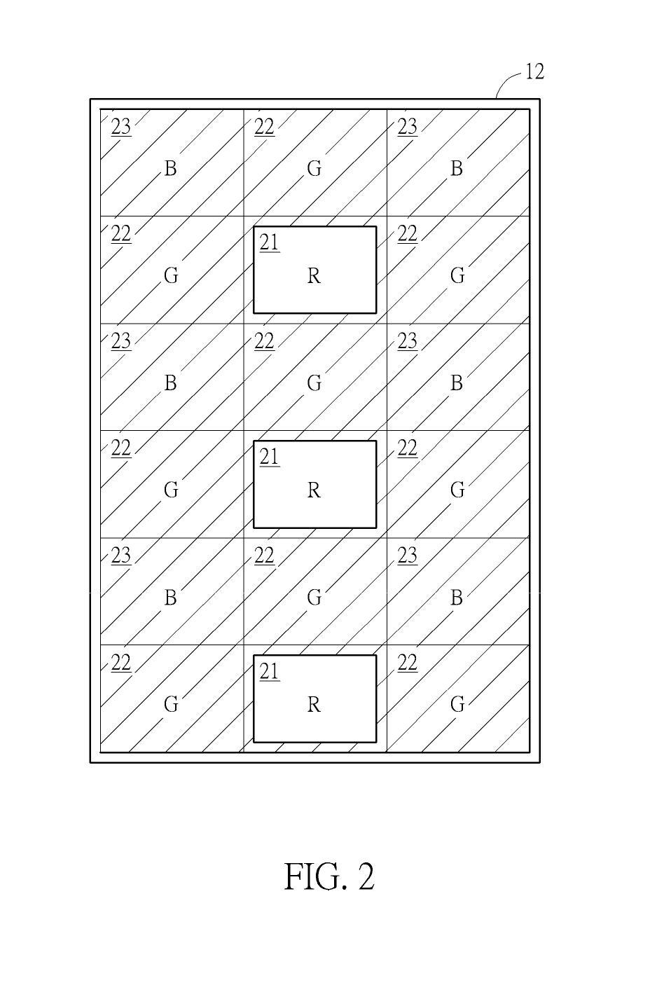

According to the embodiment, the substrate 10 has thereon a plurality of photo-sensing regions 21, 22, and 23, which respectively correspond to R, G, and B pixels of the image sensor device 1. The plurality of photo-sensing regions 21, 22, and 23 may be arranged in an array as depicted in FIG. 2. It is understood that the partial R/G/B array shown in FIG. 2 is only for illustration purposes, and in some embodiments, other arrays or patterns may be applied. The plurality of photo-sensing regions 21, 22, and 23 are separated from one another by an insulation structure 11 such as a shallow trench isolation (STI) structure.

With each of the photo-sensing regions 21, 22, and 23, a light-sensing structure is formed near the surface of the substrate 10. For example, the light-sensing structure may include a diode structure that is composed of a lightly doped well 14 and a heavily doped surface layer 16. According to the embodiment, the lightly doped well 14 has the second conductivity type and the heavily doped surface layer 16 has the first conductivity type. According to the embodiment, the first conductivity type is P type and the second conductivity type is N type.

It is to be understood by those skilled in the art that the image sensor device 1 may further comprise a transistor structure, for example, a select transistor, a transfer transistor, and/or a reset transistor. These transistors are not shown in the figures for the sake of simplicity.

At least one dielectric layer 30 is provided on the substrate 10. A metal interconnection structure (not shown) may be provided in the dielectric layer 30. A color filter film 40 is formed on the dielectric layer 30. A micro-lens layer 50 is then formed on the color filter film 40. The color filter film 40 may be arranged in an array as depicted in FIG. 2 and may include color filtering regions 41, 42, and 43 corresponding to the photo-sensing regions 21, 22, and 23 respectively. The micro-lens layer 50 may be arranged in an array including lens regions 51, 52, and 53 to converge or concentrate the incident light onto the photo-sensing regions 21, 22, and 23 respectively. Since the color filter film 40 and the micro-lens layer 50 are elements well known in the art, the further details thereof are therefore omitted.

It is one technical feature of the invention that within the substrate 10, a deep well structure 12 is provided. The deep well structure 12 has the second conductivity type, for example, N type in the embodiment. When viewed from the above, the deep well structure 12 only overlaps with the photo-sensing regions 22 and 23. That is, the deep well structure 12 only overlaps with the G and B pixels. The deep well structure 12 does not overlap with the photo-sensing region 21, as shown in FIG. 2. The deep well structure 12 has an opening corresponding to the photo-sensing region 21. It is advantageous to use such deep well structure 12 because a deeper adsorption depth for the light in far-infrared to infrared wavelength range may be obtained in the R pixels, thereby improving the quantum efficiency. In operation, a positive voltage such as V_{CC} may be applied to the deep well structure 12 with the second conductivity type, to thereby alleviate or eliminate the cross talk.

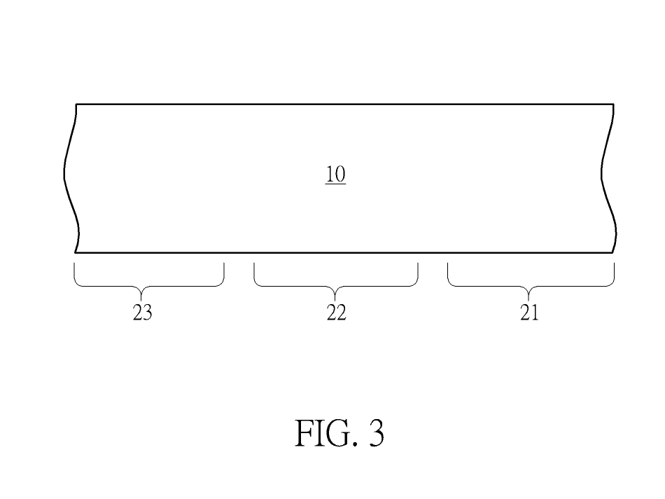

Please refer to FIG. 3 to FIG. 6. FIG. 3 to FIG. 6 are schematic diagrams showing a method for fabricating an image sensor device according to another embodiment of the invention. First, as shown in FIG. 3, a substrate 10 is provided. For example, the substrate 10 may be a semiconductor substrate having a first conductivity type such as P type. According to the embodiment, the substrate 10 may comprise an epitaxial layer (not shown), for example, a P− epitaxial silicon layer grown on a P+ silicon substrate, but not limited thereto. According to the embodiment, the substrate 10 has thereon a plurality of photo-sensing regions 21, 22, and 23, which respectively correspond to R, G, and B pixels of the image sensor device 1. The plurality of photo-sensing regions 21, 22, and 23 may be arranged in an array as depicted in FIG. 2.

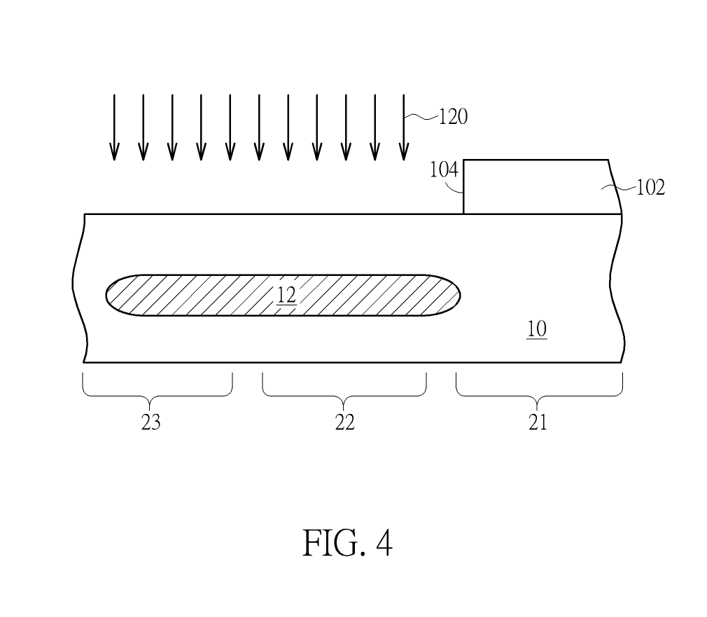

As shown in FIG. 4, a photoresist pattern 102 is formed on the substrate 10. The photoresist pattern 102 has an opening 104 exposing the photo-sensing regions 22 and 23, while the photo-sensing region 21 is masked by the photoresist pattern 102. An ion implantation process 120 is performed to implant dopants such as N type dopants into the substrate 10 through the opening 104, thereby forming the deep well structure 12 having the second conductivity type such as N type.

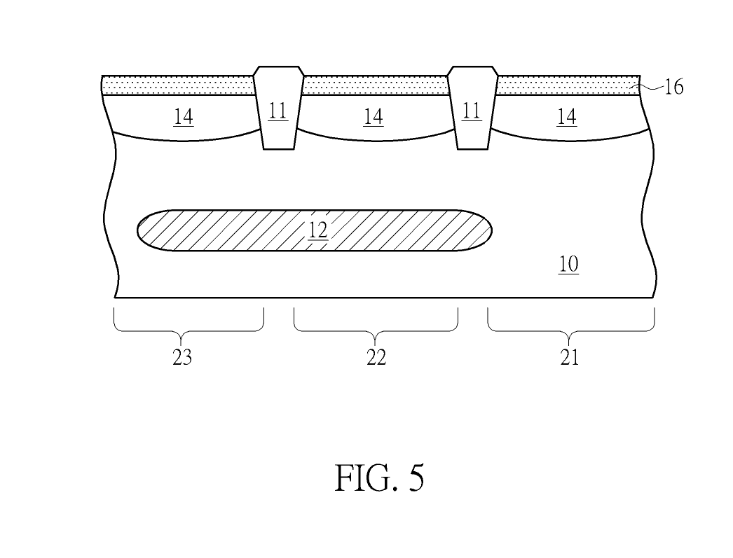

As shown in FIG. 5, subsequently, an insulation structure 11 such as a shallow trench isolation (STI) structure is formed on the substrate 10. The insulation structure 11 separates the photo-sensing regions 21, 22, and 23 from one another. Thereafter, a light-sensing structure such as a diode structure that is composed of a lightly doped well 14 and a heavily doped surface layer 16 are formed within the photo-sensing regions 21, 22, and 23. According to the embodiment, the lightly doped well 14 has the second conductivity type and the heavily doped surface layer 16 has the first conductivity type. According to the embodiment, the first conductivity type is P type and the second conductivity type is N type.

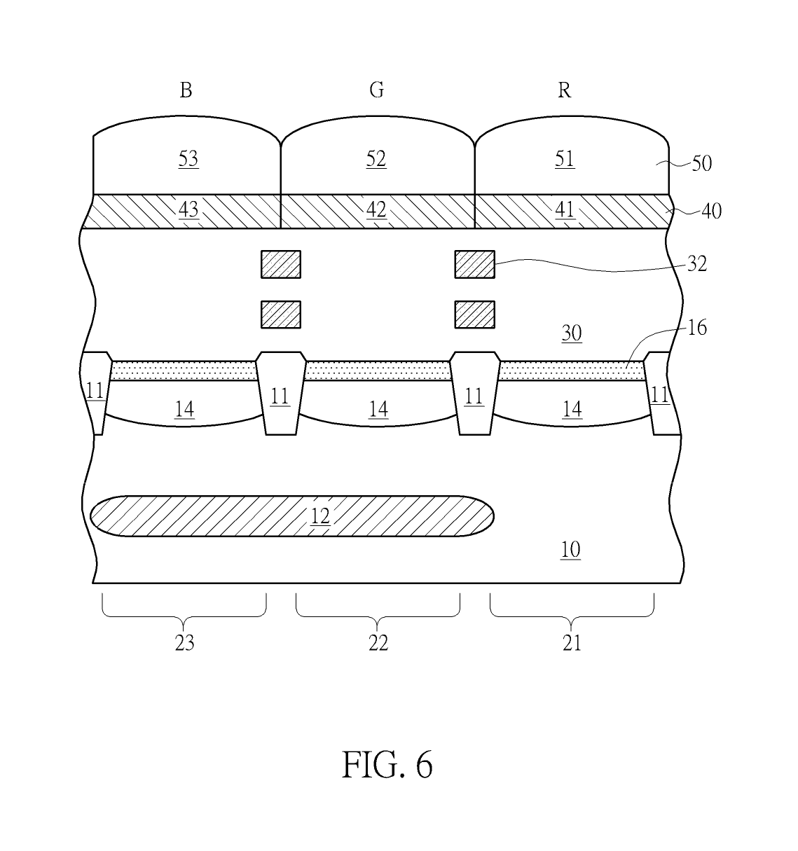

As shown in FIG. 6, a dielectric layer 30 is then formed on the substrate 10. A metal interconnection structure 32 may be provided in the dielectric layer 30. A color filter film 40 is formed on the dielectric layer 30. A micro-lens layer 50 is then formed on the color filter film 40. The color filter film 40 may be arranged in an array as depicted in FIG. 2 and may include color filtering regions 41, 42, and 43 corresponding to the photo-sensing regions 21, 22, and 23 respectively. The micro-lens layer 50 may be arranged in an array including lens regions 51, 52, and 53 to converge or concentrate the incident light onto the photo-sensing regions 21, 22, and 23 respectively.

Those skilled in the art will readily observe that numerous modifications and alterations of the device and method may be made while retaining the teachings of the invention. Accordingly, the above disclosure should be construed as limited only by the metes and bounds of the appended claims.

1. An image sensor device, comprising:
a semiconductor substrate having a first conductivity type, wherein a plurality of photo-sensing regions are provided on the semiconductor substrate;
an insulation structure disposed on the semiconductor substrate to separate the photo-sensing regions from one another;
a light-sensing structure is formed in the semiconductor substrate within each of the photo-sensing regions; and
a deep well structure having a second conductivity type, wherein the deep well structure is disposed only under some of the photo-sensing regions.

2. The image sensor device according to claim 1, wherein the semiconductor substrate comprises an epitaxial layer.

3. The image sensor device according to claim 2, wherein the epitaxial layer is a P− epitaxial silicon layer grown on a P+ silicon substrate.

4. The image sensor device according to claim 1, wherein the light-sensing structure comprises a diode structure that is composed of a lightly doped well having the second conductivity and a heavily doped surface layer having the first conductivity.

5. The image sensor device according to claim 4, wherein the first conductivity type is P type and the second conductivity type is N type.

6. The image sensor device according to claim 1 further comprising a dielectric layer on the semiconductor substrate.

7. The image sensor device according to claim 6 further comprising a color filter film and a micro-lens layer disposed on the dielectric layer.

8. The image sensor device according to claim 1, wherein the plurality of photo-sensing regions comprise a first, a second, and a third photo-sensing regions respectively correspond to R, G, and B pixels.

9. The image sensor device according to claim 8, wherein the deep well structure is disposed only under the second and third photo-sensing regions.

10-18. (canceled)
